(19) United States
(12) Patent Application Publication
(10) Pub. No.: US 2024/0321974 A1
(43) Pub. Date: Sep. 26, 2024

(54) SEMICONDUCTOR DEVICE AND SEMICONDUCTOR MODULE

(71) Applicants: Kabushiki Kaisha Toshiba, Tokyo (JP); Toshiba Electronic Devices & Storage Corporation, Tokyo (JP)

(72) Inventors: Hideki SEKIGUCHI, Yokohama Kanagawa (JP); Akira YOSHIOKA, Yokohama Kanagawa (JP); Toru SUGIYAMA, Musashino Tokyo (JP); Yasuhiro ISOBE, Narashino Chiba (JP)

(21) Appl. No.: 18/456,855

(22) Filed: Aug. 28, 2023

(30) Foreign Application Priority Data
Mar. 23, 2023 (JP) 2023-046868

(51) Int. Cl. H01L 29/40; H01L 29/417; H01L 29/778

(52) U.S. Cl. CPC H01L 29/404; H01L 29/41775; H01L 29/7786

(57) ABSTRACT

A semiconductor device includes first and second semiconductor layers, first to third electrodes, an insulating region and a conductive layer. The second semiconductor layer is located on the first semiconductor layer. The first electrode is located on the second semiconductor layer. The second electrode is located on the second semiconductor layer and arranged with the first electrode in a second direction. The third electrode is positioned between the first electrode and the second electrode. The insulating region is located on the second semiconductor layer. The insulating region is between the first electrode and the second electrode and next to the first electrode. The insulating region includes first and second insulating portions. The second insulating portion is positioned above the first insulating portion. The conductive layer is located between the first insulating portion and the second insulating portion. The conductive layer is electrically connected with the first electrode.

### CROSS-REFERENCE TO RELATED APPLICATIONS

This application is based upon and claims the benefit of priority from Japanese Patent Application No. 2023-046868, filed on Mar. 23, 2023; the entire contents of which are incorporated herein by reference.

### FIELD

Embodiments relate to a semiconductor device a semiconductor module.

### BACKGROUND

In a semiconductor device such as a transistor or the like that uses a nitride semiconductor, there are cases where a characteristic change such as an on-resistance increase or the like may occur due to, for example, repeated switching operations, etc.

### BRIEF DESCRIPTION OF THE DRAWINGS

FIG. 1 is a schematic cross-sectional view illustrating a semiconductor device according to an embodiment;

FIG. 2 is a schematic plan view illustrating the semiconductor device according to the embodiment;

FIG. 3 is a schematic plan view illustrating a modification of the conductive layer;

FIGS. 4A and 4B are schematic cross-sectional views illustrating semiconductor devices;

FIG. 5 is a schematic cross-sectional view illustrating another semiconductor device according to the embodiment;

FIG. 6 is a schematic plan view illustrating the other semiconductor device according to the embodiment; and

FIGS. 7A and 7B are schematic circuit diagrams illustrating circuits.

### DETAILED DESCRIPTION

A semiconductor device according to one embodiment, includes a first semiconductor layer, a second semiconductor layer, a first electrode, a second electrode, a third electrode, an insulating region and a conductive layer. The first semiconductor layer includes a nitride semiconductor. The second semiconductor layer is located on the first semiconductor layer. The second semiconductor layer includes a nitride semiconductor. The first electrode is located on the second semiconductor layer. The second electrode is located on the second semiconductor layer and arranged with the first electrode in a second direction crossing a first direction. The first direction is from the first semiconductor layer toward the second semiconductor layer. The third electrode is positioned above the second semiconductor layer with an insulating film part interposed. The third electrode is positioned between the first electrode and the second electrode. The insulating region is located on the second semiconductor layer. The insulating region is between the first electrode and the second electrode and next to the first electrode. The insulating region includes a first insulating portion and a second insulating portion. The second insulating portion is positioned above the first insulating portion. The conductive layer is located between the first insulating portion and the second insulating portion. The conductive layer is electrically connected with the first electrode.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

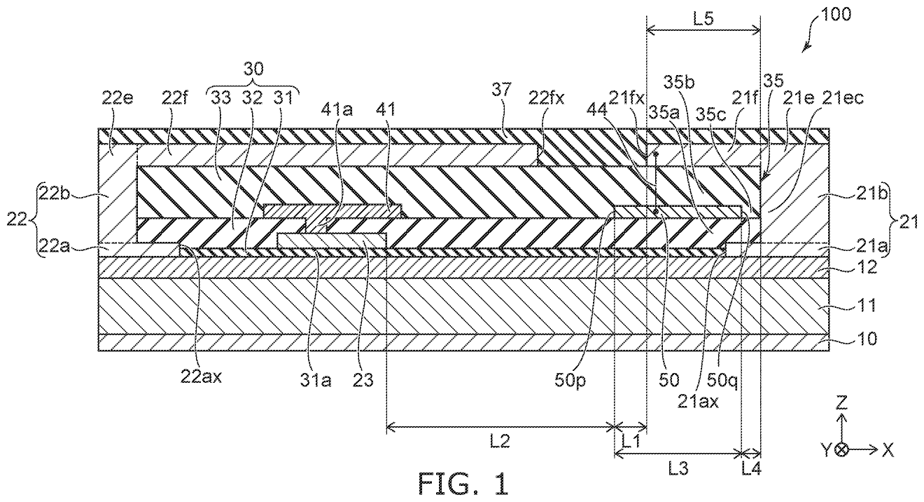

FIG. 1 is a schematic cross-sectional view illustrating a semiconductor device according to an embodiment.

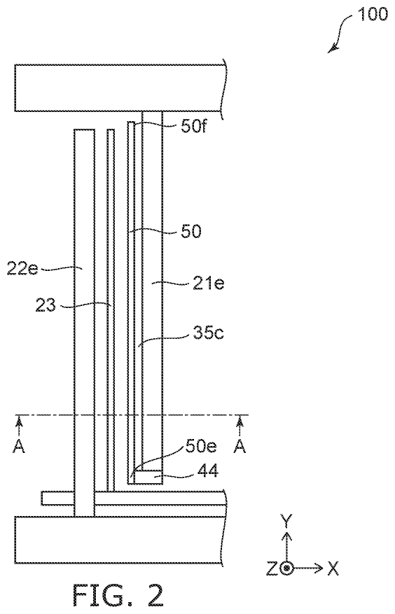

FIG. 2 is a schematic plan view illustrating the semiconductor device according to the embodiment.

FIG. 2 illustrates the planar arrangement of a portion of the semiconductor device 100 shown in FIG. 1. FIG. 1 corresponds to a cross section along line A-A shown in FIG. 2.

In FIG. 1, a HEMT (High Electron Mobility Transistor) is illustrated as an example of the semiconductor device 100 according to the embodiment. As illustrated in FIG. 1, the semiconductor device 100 includes a semiconductor layer 10, a first semiconductor layer 11, a second semiconductor layer 12, a first electrode 21, a second electrode 22, a third electrode 23, an insulating layer 30, and a conductive layer 50.

An XYZ orthogonal coordinate system is used in the description of embodiments. The direction from the first semiconductor layer 11 toward the second semiconductor layer 12 is taken as a Z-direction (a first direction). Two mutually-orthogonal directions perpendicular to the Z-direction are taken as an X-direction and a Y-direction. In the description, the direction from the first semiconductor layer 11 toward the second semiconductor layer 12 may be called “up”, and the opposite direction may be called “down”. These directions are based on the relative positional relationship between the first semiconductor layer 11 and the second semiconductor layer 12 and are independent of the direction of gravity.

The first semiconductor layer 11 is located on the semiconductor layer 10. The first semiconductor layer 11 includes a nitride semiconductor.

The second semiconductor layer 12 is located on the first semiconductor layer 11. For example, the second semiconductor layer 12 contacts the first semiconductor layer 11. The second semiconductor layer 12 includes a nitride semiconductor. For example, the first semiconductor layer 11 and the second semiconductor layer 12 form a heterojunction.

The first electrode 21 is, for example, a drain electrode. The first electrode 21 is located on a portion of the second semiconductor layer 12. The first electrode 21 is electrically connected with the second semiconductor layer 12 and has, for example, an ohmic contact with the upper surface of the second semiconductor layer 12.

In the example, the first electrode 21 includes a first lower part 21a and a first upper part 21b. The first lower part 21a contacts the second semiconductor layer 12. The first upper part 21b is positioned on the first lower part 21a and contacts (or is continuous with) the first lower part 21a. The material of the first lower part 21a and the material of the first upper part 21b may be the same or different from each other. Thus, the first electrode 21 may have a stacked structure, or may have a structure in which the first lower part 21a and the first upper part 21b are formed to have a continuous body as one layer.

In the example, the first upper part 21b includes a first electrode part 21e, and a first extension part 21f extending from the upper end portion of the first electrode part 21e in the X-direction. For example, the first electrode part 21e and the first extension part 21f may be one conductive layer (metal layer) formed from the same material to have a continuous body. According to the embodiment, the first extension part 21f may not always be provided and may be omitted as appropriate.

The first electrode part 21e is positioned on a portion of the first lower part 21a. The first lower part 21a extends further toward the second electrode 22 side than the first electrode part 21e. In other words, an end portion 21ax of the first lower part 21a at the second electrode 22 side is positioned between the first electrode part 21e and the second electrode 22 in the X-direction.

The first extension part 21f extends further toward the second electrode 22 than the first lower part 21a and covers the first lower part 21a. In other words, an end portion 21fx of the first extension part 21f at the second electrode 22 side is positioned between the second electrode 22 and the end portion 21ax of the first lower part 21a in the X-direction.

The second electrode is, for example, a source electrode. The second electrode 22 is located on a portion of the second semiconductor layer 12. The second electrode 22 is arranged with the first electrode 21 in the X-direction. The second electrode 22 is electrically connected with the second semiconductor layer 12 and has, for example, an ohmic contact with the upper surface of the second semiconductor layer 12.

In the example, the second electrode 22 includes a second lower part 22a and a second upper part 22b. The second lower part 22a contacts the second semiconductor layer 12. The second upper part 22b is positioned on the second lower part 22a and contacts (or is continuous with) the second lower part 22a.

The material of the second lower part 22a and the material of the second upper part 22b may be the same or different from each other. Thus, the second electrode 22 may have a stacked structure and may have a structure in which the second lower part 22a and the second upper part 22b are formed to have a continuous body as one layer.

In the example, the second upper part 22b includes a second electrode part 22e, and a second extension part 22f extending in the X-direction from the upper end portion of the second electrode part 22e. For example, the second electrode part 22e and the second extension part 22f may be one conductive layer (metal layer) formed from the same material to have a continuous body.

The second electrode part 22e is positioned on a portion of the second lower part 22a. The second lower part 22a extends further toward the first electrode 21 side than the second electrode part 22e. In other words, an end portion 22ax of the second lower part 22a at the second electrode 22 side is positioned between the second electrode part 22e and the first electrode 21 in the X-direction.

The second extension part 22f extends further toward the first electrode 21 than the first lower part 21a and covers the second lower part 22a. In other words, an end portion 22fx of the second extension part 22f at the first electrode 21 side is positioned between the first electrode 21 and the end portion 22ax of the second lower part 22a in the X-direction.

The second extension part 22f also extends further toward the first electrode 21 than the third electrode 23 and covers the third electrode 23 and a first conductive member 41. In other words, the end portion 22fx of the second extension part 22f is positioned between the third electrode 23 and the first electrode 21 in the X-direction. For example, the second extension part 22f functions as a field plate electrode.

The third electrode 23 is, for example, a gate electrode. The third electrode 23 is positioned above the second semiconductor layer 12 with an insulating film part 31a interposed. That is, the insulating film part 31a is located on the second semiconductor layer 12; and the third electrode 23 is located on the insulating film part 31a. The third electrode 23 is insulated from the second semiconductor layer 12 by the insulating film part 31a. The third electrode 23 is positioned between the first electrode 21 and the second electrode 22 (the second lower part 22a and the second electrode part 22e).

The third electrode 23 is located more proximate to the second electrode 22 than the first electrode 21. The distance along the X-direction between the third electrode 23 and the first electrode 21 (the first lower part 21a or the first electrode part 21e) is greater than the distance along the X-direction between the third electrode 23 and the second electrode 22 (the second lower part 22a or the second electrode part 22e).

In the example, the first conductive member 41 is located above the third electrode 23. The first conductive member 41 is electrically connected with the third electrode 23 by a connection part 41a and covers the third electrode 23. For example, the first conductive member 41 functions as a field plate electrode.

The third electrode 23 is insulated from the first and second electrodes 21 and 22 by the insulating layer 30. In the example, the insulating layer 30 includes a first insulating film 31 located on the second semiconductor layer 12, a second insulating film 32 located on the first insulating film 31, and a third insulating film 33 located on the second insulating film 32. Thus, the insulating layer 30 may have a stacked structure.

The first insulating film 31 is located between the first lower part 21a and the second lower part 22a. The insulating film part 31a described above is a portion of the first insulating film 31. The second insulating film 32 is located between the first electrode part 21e and the second electrode part 22e and covers the third electrode 23. The first conductive member 41 and the conductive layer 50 are located on the second insulating film 32. The third insulating film 33 is located between the first electrode part 21e and the second electrode part 22e and covers the first conductive member 41 and the conductive layer 50. The first extension part 21f and the second extension part 22f are located on the third insulating film 33.

As illustrated in FIG. 1, the insulating layer 30 includes an insulating region 35 that is between the first electrode 21 and the second electrode 22 and next to the first electrode 21. The insulating region 35 is arranged with the first electrode part 21e in the X-direction. For example, the insulating region 35 is a region below the first extension part 21f in contact with the first electrode 21.

The insulating region 35 includes a first insulating portion 35a, and a second insulating portion 35b positioned above the first insulating portion 35a. In the example, the first insulating portion 35a is a portion of the second insulating film 32; and the second insulating portion 35b is a portion of the third insulating film 33. The first insulating portion 35a contacts the first electrode part 21e. The second insulating portion 35b contacts the first electrode part 21e and the first extension part 21f.

The conductive layer 50 is located between the first insulating portion 35a and the second insulating portion 35b. For example, the conductive layer 50 includes a portion located below the first extension part 21f. The conductive layer 50 is arranged with an intermediate portion 21ec of the first electrode part 21e in the X-direction. The intermediate portion 21ec is between the upper end portion of the first electrode part 21e and the lower end portion of the first electrode part 21e. The conductive layer 50 may not overlap the first electrode part 21e in the Z-direction.

The Y-direction length of the conductive layer 50 may be equal to or different from the Y-direction length of the first electrode 21 and/or the Y-direction length of the second electrode 22. For example, as illustrated in FIG. 2, an end portion 50e in the Y-direction of the conductive layer 50 may not be arranged with the first electrode 21 (the first electrode part 21e) in the X-direction. An end portion 50f in the Y-direction of the conductive layer 50 may not be arranged with the second electrode 22 (the second electrode part 22e) in the X-direction.

In the example, the insulating layer 30 includes a third insulating portion 35c arranged with the conductive layer 50 in a direction (e.g., the X-direction) perpendicular to the Z-direction. The third insulating portion 35c is located between the conductive layer 50 and the first electrode part 21e. That is, at least a portion of the conductive layer 50 is separated from the first electrode 21 in the X-direction. For example, the conductive layer 50 does not directly contact the first electrode 21. The third insulating portion 35c is, for example, a portion of the insulating region 35 and may be a portion of the third insulating film 33. The third insulating portion 35c contacts the first electrode part 21e.

As illustrated in FIG. 1, an insulating layer 37 is located on the first electrode 21, the second electrode 22, and the insulating layer 30.

The conductive layer 50 is electrically connected with the first electrode 21. The potential of the conductive layer 50 may be substantially the same potential as the potential of the first electrode 21. As one example, the conductive layer 50 is electrically connected with the first electrode 21 by a connection part 44 illustrated as a schematic circuit diagram in FIG. 1. The connection part 44 is, for example, a conductive part that is located in the insulating layer 30 and contacts a portion of the conductive layer 50 (e.g., a portion of the upper surface) and the first electrode 21 (e.g., the first extension part 21f). The connection part 44 is not limited thereto, and may have an appropriate arrangement and shape contacting a portion of the conductive layer 50 and a portion of the first electrode 21. For example, as illustrated in FIG. 2, the connection part 44 may be located at the Y-direction end portion of the conductive layer 50.

Or, the conductive layer 50 may directly contact the first electrode 21. For example, as illustrated in FIG. 1, the conductive layer 50 includes two X-direction end portions (an end portion 50p at the third electrode 23 side and an end portion 50q at the first electrode 21 side). The end portion 50q is positioned between the end portion 50p and the first electrode 21. As one example, a portion of the conductive layer 50 may extend in the X-direction in FIG. 1 so that the end portion 50q of the conductive layer 50 contacts the first electrode 21. In such a case, the connection part 44 and the third insulating portion 35c are omissible as appropriate.

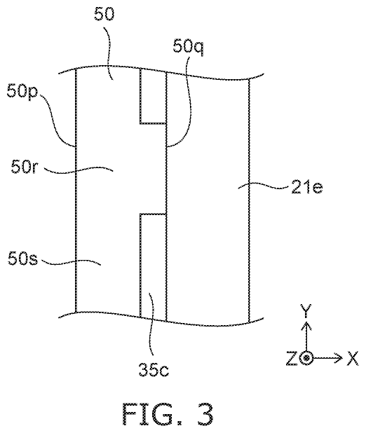

FIG. 3 is a schematic plan view illustrating a modification of the conductive layer.

As illustrated in FIG. 3, a portion 50r of the conductive layer 50 may contact the first electrode 21; and another portion 50s of the conductive layer 50 arranged with the portion 50r of the conductive layer 50 in the Y-direction may be separated from the first electrode 21 in the X-direction.

The method of electrically connecting the conductive layer 50 to the first electrode 21 is not limited to those described above. For example, the conductive layer 50 and the first electrode 21 can be set to substantially the same potential via an external circuit.

An example of materials of the components of the semiconductor device 100 will now be described.

The semiconductor layer 10 is, for example, a buffer layer located on a semiconductor substrate (not illustrated). The semiconductor substrate includes, for example, at least one selected from the group consisting of silicon, silicon carbide, sapphire, and gallium nitride. The semiconductor layer 10 includes a nitride semiconductor.

The first semiconductor layer 11 includes, for example, Alₓ₁Ga₁₋ₓ₁N (0≤x1<1). The composition ratio x1 of Al in the first semiconductor layer 11 is, for example, not less than 0 and not more than 0.01. The first semiconductor layer 11 may be, for example, GaN.

The second semiconductor layer 12 includes, for example, Alₓ₂Ga₁₋ₓ₂N (x1<x2<1). The composition ratio x2 of Al in the second semiconductor layer 12 is, for example, not less than 0.1 and not more than 0.4.

The insulating layer 30 (the first insulating film 31, the second insulating film 32, and the third insulating film 33) and the insulating layer 37 include at least one of silicon nitride or silicon oxide.

The first lower part 21a of the first electrode 21 includes, for example, at least one of Ti or Al. The first upper part 21b of the first electrode 21 includes, for example, at least one of Ti or Al.

The second lower part 22a of the second electrode 22 includes, for example, at least one of Ti or Al. The second upper part 22b includes, for example, at least one of Ti or Al.

The third electrode 23 includes, for example, at least one selected from the group consisting of TIN, TiW, WN, Pt, Ni, and Au.

The first conductive member 41 includes, for example, at least one selected from the group consisting of Al, Cu, Au, and Ag.

The conductive layer 50 includes, for example, at least one selected from the group consisting of Al, Cu, Au, Ag, and Si (e.g., polysilicon). The conductive layer 50 is, for example, a metal layer. For example, the material of the conductive layer 50 may be different from the material of the first electrode 21 (the first lower part 21a and the first upper part 21b). The conductive layer 50 may include the same material as the first electrode 21.

Operations of the semiconductor device 100 will now be described.

A positive voltage with respect to the second electrode 22 is applied to the first electrode 21. For example, a two-dimensional electron gas (2DEG) is generated at the vicinity of the interface between the first semiconductor layer 11 and the second semiconductor layer 12 in the first semiconductor layer 11. The carrier concentration of the two-dimensional electron gas below the third electrode 23 can be controlled by controlling the voltage of the third electrode 23 referenced to the voltage of the second electrode 22. For example, a two-dimensional electron gas is generated below the third electrode 23 when the voltage of the third electrode 23 is not less than a threshold (e.g., 0 V). An on-state is thereby obtained in which electrons flow from the second electrode 22 toward the first electrode 21 via the first semiconductor layer 11. When the voltage of the third electrode 23 is less than the threshold (e.g., negative), the concentration of the two-dimensional electron gas below the third electrode 23 decreases, and, for example, the two-dimensional electron gas is substantially not generated below the third electrode 23. An off-state is thereby obtained in which electrons substantially do not flow from the second electrode 22 toward the first electrode 21 via the first semiconductor layer 11. Although a normally-on device in which the on-state is obtained when the third electrode 23 is 0 V is illustrated in the example, the embodiment may be a normally-off device in which the off-state is obtained when the third electrode 23 is 0 V.

Effects of the embodiment will now be described.

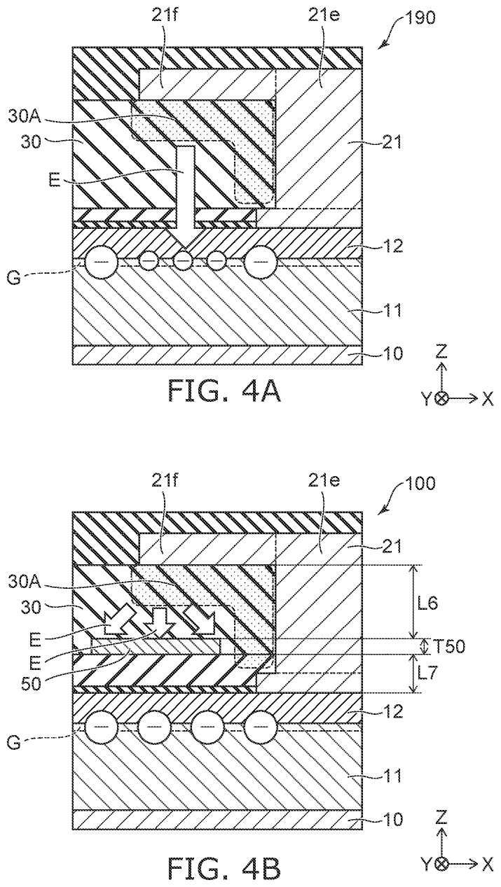

FIGS. 4A and 4B are schematic cross-sectional views illustrating semiconductor devices.

FIG. 4A illustrates the first electrode 21 vicinity of a semiconductor device 190 of a reference example; and FIG. 4B illustrates the first electrode 21 vicinity of the semiconductor device 100 described with reference to FIG. 1. The semiconductor device 190 of the reference example differs from the semiconductor device 100 in that the conductive layer 50 is not included.

For example, when a voltage is applied to the first electrode 21 in the off-state, hot electrons and mobile ions in the insulating layer 30 move to the first electrode 21 vicinity. As a result, as schematically illustrated in FIG. 4A, there is a risk that negative charge may be trapped in a region 30A of the insulating layer 30 at the vicinity of the first electrode 21. Due to the effects of an electric field E generated by the trapped negative charge, there is a possibility that the electron density of a two-dimensional electron gas G at the vicinity of the interface between the first semiconductor layer 11 and the second semiconductor layer 12 below the region 30A may decrease, and the on-resistance may increase.

In contrast, according to the embodiment, the conductive layer 50 is included as illustrated in FIG. 4B. For example, the electric field E that is generated by the negative charge trapped in the region 30A is shielded thereby. The electric field applied to the two-dimensional electron gas G by the negative charge trapped in the region 30A can be relaxed and the reduction of the electron density of the two-dimensional electron gas G can be suppressed. The increase of the on-resistance can be suppressed thereby, and stable characteristics can be obtained. For example, the current collapse can be suppressed. In the example as described above, the conductive layer 50 is electrically connected with the first electrode 21. For example, the accumulation of charge in the conductive layer 50 can be suppressed thereby, and the effects on the two-dimensional electron gas G can be suppressed.

It is desirable to provide the conductive layer 50 proximate to the first electrode 21. For example, the distance between the conductive layer 50 and the first electrode 21 is less than the distance between the conductive layer 50 and the third electrode 23. For example, as illustrated in FIG. 1, a distance L1 along the X-direction between the first electrode 21 and the end portion 50p of the conductive layer 50 is less than a distance L2 along the X-direction between the third electrode 23 and the end portion 50p of the conductive layer 50. For example, a length L4 along the X-direction of the third insulating portion 35c is less than a length L3 along the X-direction of the conductive layer 50. For example, the end portion 50q of the conductive layer 50 may be positioned directly above the first lower part 21a of the first electrode 21. Thus, by providing the conductive layer 50 proximate to the first electrode 21, the effects on the two-dimensional electron gas G of the electric field that is generated by the negative charge trapped in the region 30A at the vicinity of the first electrode 21 can be further suppressed. By providing the conductive layer 50 relatively distant to the third electrode 23, the conductive layer 50 can suppress the effects on the device characteristics (e.g., the electric field distribution at the periphery of the third electrode 23). The distance L2 may be greater than the sum of the length L3 and the length L4.

At least a portion of the conductive layer 50 is positioned between the second semiconductor layer 12 and the first extension part 21f of the first electrode 21. In other words, at least a portion of the conductive layer 50 overlaps the first extension part 21f in the Z-direction. For example, the conductive layer 50 extends further toward the second electrode 22 side than the first extension part 21f. In other words, as illustrated in FIG. 1, the X-direction position of the end portion 50p of the conductive layer 50 is between the X-direction position of the end portion 21fx of the first extension part 21f and the X-direction position of the third electrode 23. For example, as illustrated in FIG. 1, the length L3 along the second direction of the conductive layer 50 may be greater than a length L5 along the second direction of the first extension part 21f. Thus, by forming a wide conductive layer 50, the effects on the two-dimensional electron gas G of the electric field generated by the negative charge trapped in the region 30A at the vicinity of the first electrode 21 can be further suppressed. The length along the X-direction of the conductive layer 50 may be, for example, greater than the length along the X-direction of the third electrode 23.

As described above, the conductive layer 50 and the first conductive member 41 are located on the second insulating film 32; therefore, the conductive layer 50 is arranged with the first conductive member 41 in the X-direction. For example, higher complexity of the manufacturing process of forming the conductive layer 50 can be suppressed thereby. The conductive layer 50 is not limited thereto; according to the embodiment, the conductive layer 50 may be located on the first insulating film 31. In such a case, the conductive layer 50 is arranged with the third electrode 23 in the X-direction. The conductive layer 50 may be located at a different height from the third electrode 23 and/or the first conductive member 41. For example, as illustrated in FIG. 4B, a length L6 along the Z-direction between the first extension part 21f and the conductive layer 50 is greater than a length L7 along the Z-direction between the conductive layer 50 and the second semiconductor layer 12. For example, a thickness T50 of the conductive layer 50 is less than the length L7.

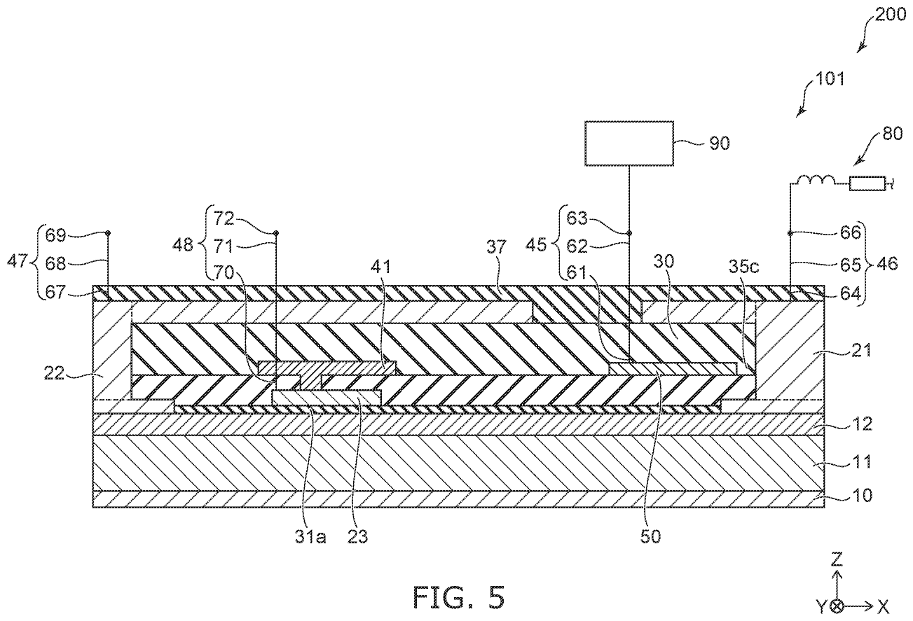

FIG. 5 is a schematic cross-sectional view illustrating another semiconductor device according to the embodiment.

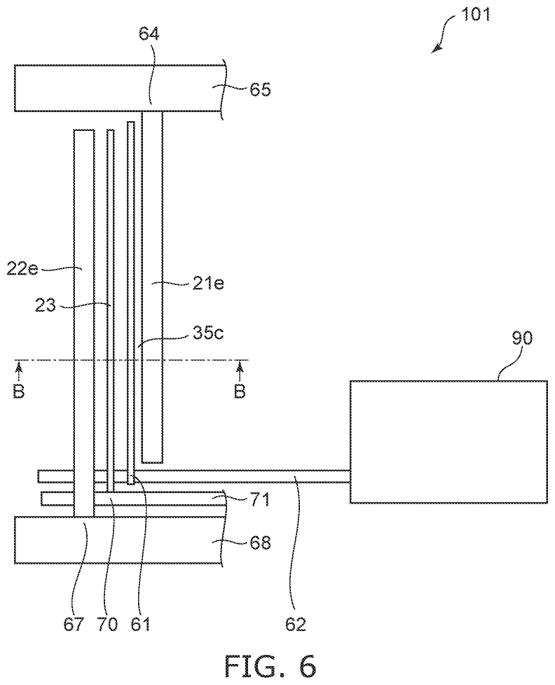

FIG. 6 is a schematic plan view illustrating the other semiconductor device according to the embodiment.

FIG. 6 illustrates the planar arrangement of a portion of the semiconductor device 101 shown in FIG. 5. FIG. 5 corresponds to a cross section along line B-B shown in FIG. 6.

In the semiconductor device 101 according to the embodiment as illustrated in FIGS. 5 and 6, the conductive layer 50 is electrically connected with a circuit 90. In the semiconductor device 101, the conductive layer 50 is not electrically connected to the first electrode 21. For example, the conductive layer 50 is insulated from the first electrode 21 by the insulating layer 30 without contacting the first electrode 21.

The circuit 90 can set the potential of the conductive layer 50 to have a lower potential than the first electrode 21. For example, the circuit 90 functions as a discharging circuit that discharges charge accumulated in the conductive layer 50. For example, the accumulation of charge in the conductive layer 50 can be suppressed thereby, and the effects on the two-dimensional electron gas G can be suppressed.

“Connected to the circuit 90” includes being connected to the circuit 90 as well as being connectable to the circuit 90.

The semiconductor device 101 includes, for example, connection parts 45, 46, 47, and 48 illustrated as schematic circuit diagrams in FIG. 5. The connection part 45 electrically connects the conductive layer 50 and the circuit 90. Specifically, the connection part 45 includes an electrode pad 63 (or a terminal), a conductive contact part 61 that contacts the conductive layer 50, and a wiring part 62 that electrically connects the contact part 61 and the electrode pad 63.

Similarly, the connection part 46 is connected to the first electrode 21; and the connection part 47 is connected to the second electrode 22. The connection part 46 includes, for example, an electrode pad 66 (or a terminal), a conductive contact part 64 that contacts the first electrode 21, and a wiring part 65 that electrically connects the contact part 64 and the electrode pad 66. The connection part 47 includes, for example, an electrode pad 69 (or a terminal), a conductive contact part 67 that contacts the second electrode 22, and a wiring part 68 that electrically connects the contact part 67 and the electrode pad 69. The connection part 48 includes, for example, an electrode pad 72 (or a terminal), a conductive contact part 70 that contacts the third electrode 23, and a wiring part 71 that electrically connects the contact part 70 and the electrode pad 72. For example, the electrode pads are exposed at the surface of the semiconductor device 101 and are configured so that an external circuit can be connected.

For example, a semiconductor module 200 (a power module) includes the semiconductor device 101 and the circuit 90. In the semiconductor module 200, the electrode pad 63 is electrically connected to the circuit 90; and the first electrode 21 (the electrode pad 66) is connected to a load 80. The load 80 is an external load (an external element) including at least one of an electrical resistance, an inductor, or a capacitor. The external load may be connected to the second electrode 22 (the electrode pad 69).

For example, the semiconductor module 200 may include multiple semiconductor devices 101. A bridge circuit may be configured using multiple semiconductor devices 101 (transistors). For example, an external load may be connected with the first electrode 21 of one semiconductor device 101 and connected with the second electrode of another semiconductor device 101. The wiring parts and/or the electrode pads may be shared by the multiple semiconductor devices 101 as appropriate. In other words, for example, one electrode pad may be electrically connected with multiple transistors. The electrode pad may be an external terminal. Each connection part is, for example, a metal part. Each connection part can include, for example, at least one selected from the group consisting of Al, Cu, Au, and Ag.

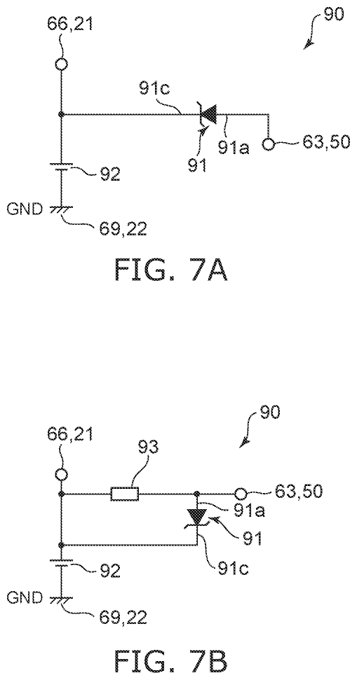

FIGS. 7A and 7B are schematic circuit diagrams illustrating circuits.

In the example illustrated in FIG. 7A, the circuit 90 includes a Zener diode 91 and is connected with a power supply part 92. The power supply part 92 is connected between the first electrode 21 (the electrode pad 66) and the second electrode 22 (the electrode pad 69). A voltage that is positive when referenced to the potential of the second electrode 22 (e.g., a ground GND) is thereby applied to the first electrode 21. An anode 91a of the Zener diode 91 is electrically connected with the conductive layer 50 (the electrode pad 63). A cathode 91c of the Zener diode 91 is electrically connected with the first electrode 21. Accordingly, the conductive layer 50 has a lower voltage than the first electrode 21 by the amount of a prescribed voltage determined by the Zener diode 91. The potential difference between the conductive layer 50 and the first electrode 21 may be appropriately determined according to the positional relationship between the conductive layer 50 and the first electrode 21 and/or the potential of the first electrode 21, and is, for example, greater than 0 V and not more than about 100 V.

FIG. 7B illustrates another example of the circuit 90. In FIG. 7B, the circuit 90 further includes a resistance 93. The resistance 93 is connected in parallel with the Zener diode 91 between the first electrode 21 and the conductive layer 50. The potential of the conductive layer 50 can be set to a lower potential than the first electrode 21 by the circuit 90 that includes the Zener diode 91.

According to embodiments, a semiconductor device can be provided in which stable characteristics can be obtained.

The embodiments may include the following configurations (for example, technical proposals).

### Configuration 1

A semiconductor device, comprising:
a first semiconductor layer including a nitride semiconductor;
a second semiconductor layer located on the first semiconductor layer, the second semiconductor layer including a nitride semiconductor;
a first electrode located on the second semiconductor layer;
a second electrode located on the second semiconductor layer and arranged with the first electrode in a second direction crossing a first direction, the first direction being from the first semiconductor layer toward the second semiconductor layer;
a third electrode positioned above the second semiconductor layer with an insulating film part interposed, the third electrode being positioned between the first electrode and the second electrode;
an insulating region located on the second semiconductor layer, the insulating region being between the first electrode and the second electrode and next to the first electrode, the insulating region including a first insulating portion and a second insulating portion, the second insulating portion being positioned above the first insulating portion; and
a conductive layer located between the first insulating portion and the second insulating portion, the conductive layer being electrically connected with the first electrode.

### Configuration 2

A semiconductor device, comprising:
a first semiconductor layer including a nitride semiconductor;
a second semiconductor layer located on the first semiconductor layer, the second semiconductor layer including a nitride semiconductor;
a first electrode located on the second semiconductor layer;
a second electrode located on the second semiconductor layer, the second electrode being arranged with the first electrode in a second direction crossing a first direction, the first direction being from the first semiconductor layer toward the second semiconductor layer;
a electrode third positioned above the second semiconductor layer with an insulating film part interposed, the third electrode being positioned between the first electrode and the second electrode in the second direction;
an insulating region located on the second semiconductor layer, the insulating region being between the first electrode and the second electrode and next to the first electrode, the insulating region including a first insulating portion and a second insulating portion, the second insulating portion being positioned above the first insulating portion; and
a conductive layer located between the first insulating portion and the second insulating portion, the conductive layer being connected to a circuit, the conductive layer being set to a lower potential than the second electrode by the circuit.

### Configuration 3

The device according to Configuration 2, wherein
the circuit includes a Zener diode.

### Configuration 4

The device according to any one of Configurations 1 to 3, further comprising:
a third insulating portion located between the conductive layer and the first electrode, the third insulating portion being arranged with the conductive layer in a direction perpendicular to the first direction.

### Configuration 5

The device according to any one of Configurations 1 to 4, wherein
the conductive layer includes an end portion at the third electrode side, and
a distance along the second direction between the end portion and the first electrode is less than a distance along the second direction between the end portion and the third electrode.

### Configuration 6

The device according to any one of Configurations 1 to 5, further comprising:
a conductive member electrically connected with the third electrode,
the conductive member covering the third electrode,
the conductive layer being arranged with the conductive member in the second direction.

### Configuration 7

The device according to any one of Configurations 1 to 6, wherein
the first electrode includes:
   a first electrode part; and
   a first extension part extending from an upper end portion of the first electrode part toward the second electrode side, and
at least a portion of the conductive layer is positioned between the first extension part and the second semiconductor layer.

### Configuration 8

The device according to Configuration 7, wherein
a length along the second direction of the conductive layer is greater than a length along the second direction of the first extension part.

### Configuration 9

A semiconductor module, comprising:
the device according to Configuration 2 or 3; and
the circuit,
the device including
   a contact part contacting the conductive layer, and
   an electrode pad electrically connected with the contact part,
the circuit being electrically connected with the electrode pad,
the first electrode or the second electrode being electrically connected to an external load.

In this specification, being “electrically connected” includes not only the case of being connected in direct contact, but also the case of being connected via another conductive member, etc.

The scope of one component being “located on” another component may include not only the case where the two components contact each other (or are continuous), but also the case where another component is located between the two components. For example, the scope of one component being “located on” another component may include the case where one component is positioned above another component regardless of whether or not the two components contact each other.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A semiconductor device, comprising:
a first semiconductor layer including a nitride semiconductor;
a second semiconductor layer located on the first semiconductor layer, the second semiconductor layer including a nitride semiconductor;
a first electrode located on the second semiconductor layer;
a second electrode located on the second semiconductor layer and arranged with the first electrode in a second direction crossing a first direction, the first direction being from the first semiconductor layer toward the second semiconductor layer;
a third electrode positioned above the second semiconductor layer with an insulating film part interposed, the third electrode being positioned between the first electrode and the second electrode;
an insulating region located on the second semiconductor layer, the insulating region being between the first electrode and the second electrode and next to the first electrode, the insulating region including a first insulating portion and a second insulating portion, the second insulating portion being positioned above the first insulating portion; and
a conductive layer located between the first insulating portion and the second insulating portion, the conductive layer being electrically connected with the first electrode.

2. A semiconductor device, comprising:
a first semiconductor layer including a nitride semiconductor;
a second semiconductor layer located on the first semiconductor layer, the second semiconductor layer including a nitride semiconductor;
a first electrode located on the second semiconductor layer;
a second electrode located on the second semiconductor layer, the second electrode being arranged with the first electrode in a second direction crossing a first direction, the first direction being from the first semiconductor layer toward the second semiconductor layer;
a third electrode positioned above the second semiconductor layer with an insulating film part interposed, the third electrode being positioned between the first electrode and the second electrode in the second direction;
an insulating region located on the second semiconductor layer, the insulating region being between the first electrode and the second electrode and next to the first electrode, the insulating region including a first insulating portion and a second insulating portion, the second insulating portion being positioned above the first insulating portion; and
a conductive layer located between the first insulating portion and the second insulating portion, the conductive layer being connected to a circuit, the conductive layer being set to a lower potential than the second electrode by the circuit.

3. The device according to claim 2, wherein
the circuit includes a Zener diode.

4. The device according to claim 1, further comprising:
a third insulating portion located between the conductive layer and the first electrode, the third insulating portion being arranged with the conductive layer in a direction perpendicular to the first direction.

5. The device according to claim 1, wherein
the conductive layer includes an end portion at the third electrode side, and
a distance along the second direction between the end portion and the first electrode is less than a distance along the second direction between the end portion and the third electrode.

6. The device according to claim 1, further comprising:
a conductive member electrically connected with the third electrode,
the conductive member covering the third electrode,
the conductive layer being arranged with the conductive member in the second direction.

7. The device according to claim 1, wherein
the first electrode includes:
a first electrode part; and
a first extension part extending from an upper end portion of the first electrode part toward the second electrode side, and
at least a portion of the conductive layer is positioned between the first extension part and the second semiconductor layer.

8. The device according to claim 7, wherein
a length along the second direction of the conductive layer is greater than a length along the second direction of the first extension part.

9. A semiconductor module, comprising:
the device according to claim 2; and
the circuit,
the device including
a contact part contacting the conductive layer, and
an electrode pad electrically connected with the contact part,
the circuit being electrically connected with the electrode pad,
the first electrode or the second electrode being electrically connected to an external load.
